(19) United States
(12) Patent Application Publication
(10) Pub. No.: US 2022/0416051 A1
(43) Pub. Date: Dec. 29, 2022

(54) TWO-DIMENSIONAL SEMICONDUCTOR-METAL OHMIC-CONTACT STRUCTURE, PREPARATION METHOD THEREFOR AND USE THEREOF

(71) Applicant: NANJING UNIVERSITY, Nanjing (CN)

(72) Inventors: Xinran WANG, NANJING (CN); Weisheng LI, NANJING (CN); Zhihao YU, NANJING (CN); Yi SHI, NANJING (CN)

(21) Appl. No.: 17/880,311

(22) Filed: Aug. 3, 2022

(30) Foreign Application Priority Data
Apr. 29, 2022 (CN) 202210466261.7

(51) Int. Cl. H01L 29/45; H01L 21/443

(52) U.S. Cl. CPC H01L 29/45; H01L 21/443

(57) ABSTRACT

It is a two-dimensional semiconductor-metal ohmic-contact structure, a preparation method therefor and use thereof, wherein the ohmic-contact structure comprises two-dimensional semiconductor having semimetal antimony or an alloy containing semimetal antimony deposited thereon to form an ideal van der Waals interface with strong orbital hybridization, and semimetal antimony is deposited on the two-dimensional semiconductor by high-vacuum evaporation; which is applied to semiconductor devices and realizes ultralow contact resistance between the metal and the two-dimensional semiconductor and significantly improve the performance of two-dimensional semiconductor devices.

### CROSS REFERENCES

This application claims priority to Chinese Patent Application Ser. No. CN202210466261.7 filed on 29 Apr. 2022.

### TECHNICAL FIELD

The present invention relates to the semiconductor device field, and in particular to a two-dimensional semiconductor-metal ohmic-contact structure, a preparation method therefor and use thereof.

### BACKGROUND

The latest international technology roadmap for semiconductors (ITRS 2.0) indicates that two-dimensional semiconductor materials are considered to be one of the most potential candidates for channel materials of microelectronic devices in the post-Moore era due to their advantages of ultra-thin atomic-scale thickness, surface dangling bond-free, adjustable band gap, high mobility, immune short channel effect, excellent air stability, high compatibility with BEOL, random van der Waals integration and the like.

However, Fermi level pinning effect existing at metal-semiconductor (M-S) contact interface causes the formation of very high Schottky barrier and contact resistance, which severely limits the performance improvement of the two-dimensional semiconductor device, and particularly greatly influences the improvement of on-state current along with the scaling down of device size. For the typical silicon-based transistor, low contact resistance thereof is realized by performing ion beam injection heavy doping on the contact region, so that the Schottky barrier width between source/drain electrodes and channel is remarkably reduced, and the quantum tunneling probability of carriers is greatly increased. Two-dimensional materials with ultra-thin thickness are not able to tolerate the energy bombardment of high energy ion beams and are not compatible with ion beam injection process. After years of development, scientists have developed varieties of methods to reduce contact resistance, including edge contacts, low work function metals, ultra-high vacuum evaporation, low energy metal integration, tunneling contacts and the like. However, the contact resistance reported in these methods is still 1-2 orders of magnitude higher than that of silicon-based devices (100 Ω·μm), and thus still cannot meet the performance requirements of logic devices in integrated circuits.

### SUMMARY

Objective: One objective of the present invention is to provide an ohmic-contact structure, which solves the problems of large contact resistance and insufficient reliability of two-dimensional semiconductor devices.

Another objective of the present invention is to provide a preparation method for an ohmic-contact structure, which can deposit (011̅2) oriented semimetal antimony, has strong van der Waals interaction and energy band hybridization with two-dimensional semiconductor, and realizes barrier-free injection of carriers at contact interface.

Another objective of the present invention is to provide a semiconductor device having a small device size, reduced contact resistance and improved current density.

Technical solution: In order to achieve the above-mentioned objectives, the present invention provides an ohmic-contact structure, which comprises a two-dimensional semiconductor having semimetal antimony or an alloy containing semimetal antimony deposited thereon to form an ohmic contact.

Preferably, semimetal antimony is the (0112) oriented atomic structure, and the (0112) oriented antimony semimetal is characterized by effectively inhibiting the generation of metal induced energy gap state and avoiding Fermi level pinning effect, and the (0112) oriented antimony has a proper work function (˜4.2 eV), and is matched with the conduction band minimum (CBM) of two dimensional semiconductor to form Schottky barrier less than or equal to 0; the coupling between the (011̅2) oriented antimony and the two-dimensional semiconductor has small atomic distance, strong van der Waals interaction and strong orbital hybridization, and are favorable for charge transfer between interfaces; the (0112) oriented antimony has a high melting point above 630° C., has robust temperature reliability, and is compatible with semiconductor device processes.

The two-dimensional semiconductor includes any one of molybdenum disulfide (MoS₂), tungsten disulfide (WSe₂), molybdenum diselenide (MoSe₂), tungsten diselenide (WS₂), rhenium disulfide, black phosphorus, silicene, phosphorus selenide, germanene, indium selenide and tin sulfide.

The present invention provides a preparation method for an ohmic-contact structure, which comprises the following steps:

placing the two-dimensional semiconductor sample in high-vacuum evaporation system; and

heating the equipment to the preset temperature after vacuum pumping and performing vacuum evaporation process to finish the deposition of the semimetal antimony or the alloy containing semimetal antimony on the two-dimensional semiconductor.

Preferably, the vacuum pumping is performed to a vacuum degree higher than 10⁻⁶ Torr with a preset temperature range of 50-600° C., and the evaporation of metal is performed at a rate of 0.05-0.3 A/s for 1-30 nm; The slow evaporation rate at high temperature can promote the formation of (011̅2)-oriented structural alignment in antimony film

In an embodiment, the high-vacuum evaporation systems includes electron beam vacuum evaporation, magnetron sputtering vacuum evaporation or thermal vacuum evaporation, wherein the electron beam vacuum evaporation provides a precise deposition temperature and film thickness control.

The present invention provides a semiconductor device comprising an ohmic-contact structure, the semiconductor device being any one of back-gate field-effect transistors, top-gate field-effect transistors, triodes, diodes, phototransistors, junction transistors, metal-semiconductor transistors, SOI transistors, modulation doped field-effect transistors, thyristors, LEDs, photodetectors, laser diodes, power semiconductor devices, ferroelectric transistors, Fin FETs, GAA FETs, MBC FETs, CFETs and 3D EFTs.

An embodiment provides a semiconductor device applying an ohmic-contact structure, which comprises a substrate and the ohmic-contact structure deposited thereon, wherein the ohmic-contact structure has a capping layer deposited thereon, and the substrate has a gate and a gate dielectric layer.

Preferably, the gate dielectric layer is at least one of silicon oxide, hafnium oxide, aluminum oxide, zirconium oxide, lanthanum oxide, titanium oxide, boron nitride, mica, silicon nitride, PZT and HZO, and the gate is any one of a conductive metal, ITO, heavily doped silicon, graphene and a metallic carbon nanotube.

The capping layer is at least one of gold, silver, copper, aluminum, platinum, nickel, titanium, ITO, tungsten, palladium, cobalt and molybdenum.

The substrate is any one of silicon oxide, sapphire, quartz, glass, silicon nitride, polyimide, PDMS, PMMA, BCB, PET and PEN.

Beneficial effects: The present invention adopts semimetal (011̅2)-oriented antimony as the contact electrode which has the strong van der Waals interaction and energy band hybridization with two-dimensional semiconductors, thereby realizing barrier-free injection of carriers at the contact interface; semimetal antimony is robust in melting point and stability, and thus the reliability and stability of the device is enhanced; the two-dimensional semiconductor device in contact with semimetal antimony can possess more excellent performance, with the reduced contact resistance of 42 Ω·μm, low transfer length of 5.1 nm and high current density of 1.54 mA/μm under the source-drain voltage of 1.5 V, far higher than the results of silicon-based FinFET and GAAFET; the present invention can be used in many types of two-dimensional semiconductor devices and circuits.

### BRIEF DESCRIPTION OF THE DRAWINGS

FIG. 1 is the schematic structural diagram of a back-gate two-dimensional semiconductor device according to an embodiment of the present invention;

FIG. 2A is the density functional theory (DFT) calculation result of the antimony (011̅2)-molybdenum disulfide (MoS₂) contact and the antimony (0001)-MoS₂ contact, respectively, that is the energy band structure diagram of the antimony(011̅2)-MoS₂ contact;

FIG. 2B is the density functional theory (DFT) calculation result of the antimony (011̅2)-molybdenum disulfide (MoS₂) contact and the antimony (0001)-MoS₂ contact, respectively, that is the energy band structure diagram of the antimony (0001)-MoS₂ contact, solid and hollow spheres represent orbitals of MoS₂ and antimony, respectively, and the sizes of the symbols represent relative contributions;

FIG. 2C is the density functional theory (DFT) calculation result of the antimony (011̅2)-molybdenum disulfide (MoS₂) contact and the antimony (0001)-MoS₂ contact, respectively, that is the charge density near-Fermi-level (left) with the antimony (011̅2) contact and the antimony(0001) contact;

FIG. 2D is the density functional theory (DFT) calculation result of the antimony (011̅2)-molybdenum disulfide (MoS₂) contact and the antimony (0001)-MoS₂ contact, respectively, that is the differential charge density (right) with the antimony (011̅2) contact and the antimony(0001) contact;

FIG. 2E is the density functional theory (DFT) calculation result of the antimony (0112)-molybdenum disulfide (MoS₂) contact and the antimony (0001)-MoS₂ contact, respectively, that is the integrated density of states at the Fermi level with these two contacts;

FIG. 2F is the density functional theory (DFT) calculation result of the antimony (0112)-molybdenum disulfide (MoS₂) contact and the antimony (0001)-MoS₂ contact, respectively, that is the charge transfer from antimony to MoS₂ by Bader charge analysis with these two contacts;

FIG. 2G is the density functional theory (DFT) calculation result of the antimony (011̅2)-molybdenum disulfide (MoS₂) contact and the antimony (0001)-MoS₂ contact, respectively, that is the interfacial van der Waals interaction energy between antimony and MoS2 with these two contacts;

FIG. 3 is the interfacial van der Waals interaction energy of two contact structures of antimony (011̅2) and antimony (0001) with other two-dimensional semiconductor;

FIG. 4 is the XRD characterization results of the deposition of antimony film depositing on MoS₂ films for two different evaporation temperature processes;

FIG. 5 is the Raman spectrums of the 15 nm (011̅2) oriented antimony film deposited on MoS₂ film/silicon substrate according to an embodiment of the present invention;

FIG. 6 is the low temperature photoluminescence spectrum of the 5 nm (011̅2) oriented antimony film deposited on MoS₂ film on sapphire substrate according to an embodiment of the present invention;

FIG. 7 is the high resolution scanning transmission electron microscope image of the 20 nm (0112) oriented antimony film deposited on MoS₂ film on sapphire substrate according to an embodiment of the present invention;

FIG. 8A is the measurement electrical data of a back-gate transistor of monolayer MoS₂ prepared in an embodiment of the present invention that shows transfer curves for different channel lengths, with an inset of scanning electron microscope imaging of corresponding devices;

FIG. 8B is the measurement electrical data of a back-gate transistor of monolayer MoS₂ prepared in an embodiment of the present invention that shows contact resistance extraction result using the transmission line method on the devices in FIG. 8A, wherein the contact resistance is 42 Ω·μm and the transfer length is 5.1 nm when the carrier concentration is 3×10¹³ cm²;

FIG. 8C is the measurement electrical data of a back-gate transistor of monolayer MoS₂ prepared in an embodiment of the present invention that shows the benchmark of the contact resistance measurement result of the present invention with the reported results of other technologies, wherein five-pointed stars in the figure are the measurement result of the present invention, and it can be seen from the figure that our measurement data are far lower than the results of other two-dimensional semiconductor devices, even lower than the results of silicon devices and gallium nitride devices and close to the quantum limit;

FIG. 8D is the measurement electrical data of a back-gate transistor of monolayer MoS₂ prepared in an embodiment of the present invention that shows the contact resistance as a function of temperature for MoS₂-antimony (0112) contact;

FIG. 9A is the measurement data of a typical monolayer MoS₂ transistor prepared in an embodiment of the present invention that shows transfer curves of this device at different temperatures, with the source-drain voltage of 0.1 V and the channel length of 1 μm;

FIG. 9B is the measurement data of a typical monolayer MoS₂ transistor prepared in an embodiment of the present invention that shows Arrhenius curves extracted from FIG. 9A;

FIG. 9C is the measurement data of a typical monolayer MoS₂ transistor prepared in an embodiment of the present invention that shows the plot of the barrier versus the gate voltage extracted from FIG. 9B, wherein the Schottky barrier extracted from the left linear cutoff region is −20 meV;

FIG. 9D is the measurement data of a typical monolayer MoS₂ transistor prepared in an embodiment of the present invention that shows transfer curves of this device at different temperatures;

FIG. 10A is the measurement data of a typical monolayer MoS₂ transistor prepared in an embodiment of the present invention that shows transfer curves of this device with a channel length of 20 nm, with the source-drain voltages of 0.1 V, 0.55 V and 1 V, respectively. the inset is the scanning electron microscope photograph of the corresponding devices;

FIG. 10B is the measurement data of a typical monolayer MoS₂ transistor prepared in an embodiment of the present invention that shows output curves of a device with a channel length of 20 nm, wherein the solid line is the measurement result of the DC mode with the gate voltage increased from −2 V to 10 V and the step length of 2 V, and the dotted line is the measurement result of the pulse mode with the gate voltage increased from 6 V to 10 V and the step length of 2 V;

FIG. 10C is the measurement data of a typical monolayer MoS₂ transistor prepared in an embodiment of the present invention that shows the current density comparison result of different device technologies when the source-drain voltage is 1 V, wherein five-pointed stars are the result of the prior art, and it can be seen from the figure that the monolayer MoS₂ device prepared by the prior art has advancement with different channel lengths, higher than the results of other MoS₂ devices, and comparable with that of the planar silicon transistor, and higher than that of silicon-based FinFET and GAAFET;

FIG. 11A is the high temperature reliability measurement results of MoS₂ transistors with antimony (011̅2) contact and Bi-contact, respectively, that shows transfer curves of the antimony (011̅2) contact device measured at different times in the nitrogen environment at 125° C.;

FIG. 11B is the high temperature reliability measurement results of MoS₂ transistors with antimony (011̅2) contact and Bi-contact, respectively, that shows output curves of the same device measured at the initial time and after 24 h at 125° C., respectively, with the gate voltage increased from −2 V to 10 V and the step length of 2 V from bottom to top;

FIG. 11C is the high temperature reliability measurement results of MoS₂ transistors with antimony (011̅2) contact and Bi-contact, respectively, that shows output curves of the same device measured at the initial time and after 24 h at 125° C., respectively, with the gate voltage increased from −2 V to 10 V and the step length of 2 V from bottom to top;

FIG. 11D is the high temperature reliability measurement results of MoS₂ transistors with antimony (0112) contact and Bi-contact, respectively, that shows transfer curves of the Bi-contact device measured at different times in the same nitrogen environment at 125° C.;

FIG. 11E is the high temperature reliability measurement results of MoS₂ transistors with antimony (011̅2) contact and Bi-contact, respectively, is output curve of the same device measured at the initial time and after 24 h at 125° C., respectively, with the gate voltage increased from −2 V to 10 V and the step length of 2 V from bottom to top;

FIG. 11F is the high temperature reliability measurement results of MoS₂ transistors with antimony (011̅2) contact and Bi-contact, respectively, that is output curves of the same device measured at the initial time and after 24 h at 125° C., respectively, with the gate voltage increased from −2 V to 10 V and the step length of 2 V from bottom to top;

FIG. 12A is the statistical measurement results of many MoS₂ devices with antimony (011̅2) contact (63 devices) and antimony (0001) contact (41 devices) that shows statistical histograms of the contact resistance with the two contacts, respectively;

FIG. 12B is the statistical measurement results of many MoS₂ devices with antimony (0112) contact (63 devices) and antimony (0001) contact (41 devices) that shows the transfer length with the two contacts, respectively;

FIG. 12C is the statistical measurement results of many MoS₂ devices with antimony (011̅2) contact (63 devices) and antimony (0001) contact (41 devices) that shows transfer curves of >160 devices with the channel length of 100 nm, with the source-drain voltage of 1 V;

FIG. 12D is the statistical measurement results of many MoS₂ devices with antimony (011̅2) contact (63 devices) and antimony (0001) contact (41 devices) that shows the boxplot with Gaussian fitting of the on-state current extracted from FIG. 12C.

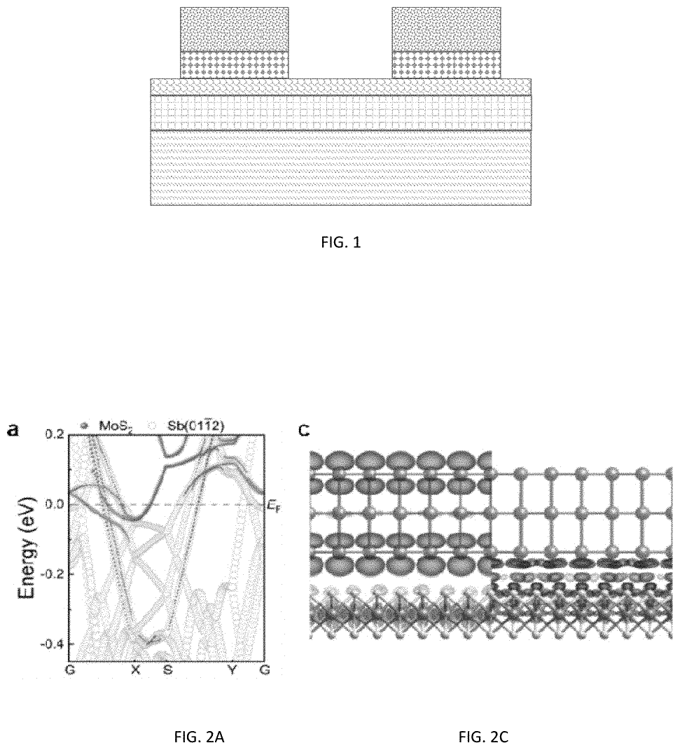

### DETAILED DESCRIPTION

The present invention is further described below with reference to the embodiments and the drawings.

According to an embodiment of the present invention, controllable deposition of semimetal antimony (011̅2) on MoS2 can be realized by optimizing the evaporation process, and the preparation process comprises the following specific steps:
(1) placing monolayer MoS2 samples in an electron beam evaporation system, performing vacuum pumping for 3 h, with the vacuum pressure of about 1×10⁻⁷ Torr, opening the heating mercury lamp, slowly heating the vacuum cavity to 150° C., and determining the temperature of the sample as 100° C. according to the measurement result of a temperature sticker; and
(2) opening the electron beam filament, heating the crucible filled with high-purity antimony particles, and performing vacuum evaporation on antimony for 20 nm; opening the shielding plate, performing the deposition process of antimony on the sample at the evaporation rate of 0.05-0.3 A/s for 1-30 nm; and venting the electron beam evaporation system when the temperature is reduced to room temperature, thereby finishing the deposition of antimony(0112) film on MoS₂.

If no heating operation is performed in the whole evaporation process, the (0001) oriented antimony film can be obtained by evaporation.

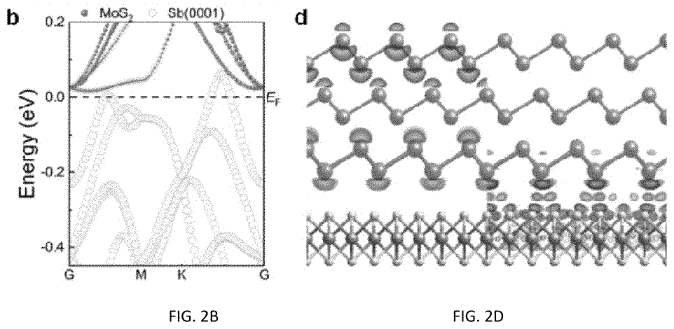

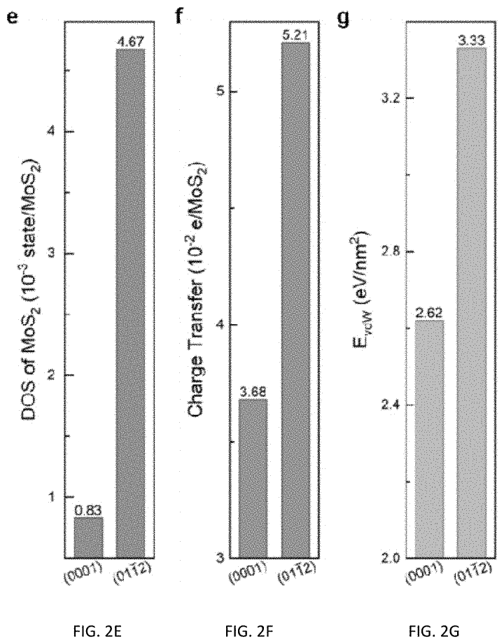

The energy band hybridization mechanism of the monolayer MoS₂ and the semimetal antimony is researched by adopting the density functional theory calculation, and the calculation result is shown in FIG. 2, wherein after antimony (011̅2)-MoS₂ contact, a plurality of hybridization energy bands formed by a d orbital of Mo, a p orbital and an s orbital of antimony are below Fermi level, and thus the conduction band minimum (CBM) of MoS₂ is effectively reduced to be about 0.4 eV below the Fermi level. For antimony (0001)-MoS₂ contact, the energy bands below the Fermi level are primarily from the p and s orbitals of antimony, and CBM of MoS₂ is above Fermi level. The visible band hybridization of these two contacts at Fermi level is represented by the partial charge distribution diagram, which shows that the charges distributed in the antimony (011̅2) and MoS₂ are more abundant than those in the antimony (0001)-MoS₂ contact. The charge transfer efficiency of these two contact interfaces is further investigated by differential charge density, as shown in the right half of FIG. 2. C-D. Energy band hybridization and charge transfer are quantified by integrating the density of states at the Fermi level position of MoS₂ and by Bader charge transfer, as shown in FIG. 2G-F. In the above comparison, the antimony (011̅2)-MoS₂ contact exhibits a reinforcing effect on the band coupling.

To explore the physical origin of the enhanced energy band hybridization and charge transfer brought about by the antimony (011̅2)-MoS₂ contact, the interfacial van der Waals interaction energy after contact is calculated as shown in FIG. 2G. It can be found by calculation that the van der Waals interaction energy of the antimony (011̅2)-MoS₂ contact is 3.33 eV/cm², which is higher than that of the antimony (0001)-MoS₂ contact (2.62 eV/cm²). This is due to the (011̅2) oriented antimony structure having more compact arrangement and atomic density at the contact interface. In addition, as shown in FIG. 3, the interfacial van der Waals interaction energy of antimony (011̅2) contacting with WSe₂, WS₂ and MoS₂ is calculated to be significantly higher than the result of antimony (0001) contact, which further proves that antimony (011̅2) has universal effect on two-dimensional semiconductors, and does not limit the two-dimensional semiconductor materials disclosed in this embodiment, but has universal effect on two-dimensional semiconductor materials such as molybdenum disulfide, tungsten disulfide, molybdenum diselenide, tungsten diselenide, rhenium disulfide, black phosphorus, silicene, phosphorus selenide, germanene, indium selenide and tin oxide.

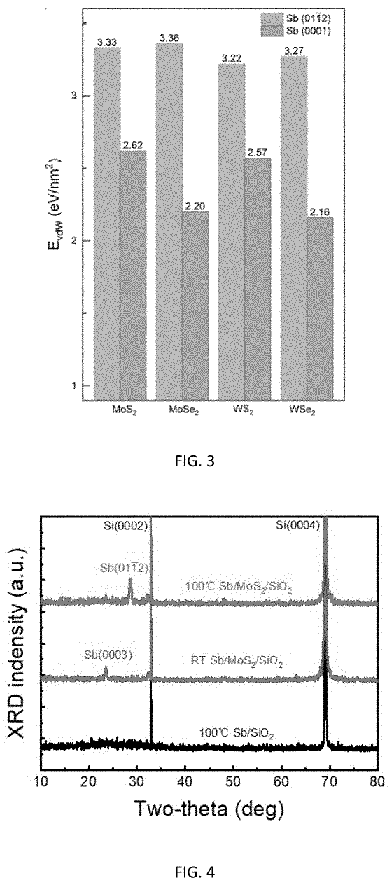

As can be seen from FIG. 4, the result obtained by the XRD characterization of the antimony films obtained by the two evaporation conditions shows that the antimony film evaporated and deposited at the high temperature (150° C.) has a strong (0112) signal peak, while the antimony film evaporated and deposited at room temperature has a weak (0003) signal peak. Therefore, it can be demonstrated that the high quality (0112) oriented antimony film can be achieved by optimizing the evaporation process, providing a key basis for the preparation of ohmic contact devices.

According to the above-mentioned tests, semimetal antimony is used as the contact electrode and has strong van der Waals interaction and energy band hybridization with two-dimensional semiconductors, so that barrier-free injection of carriers at the contact interface is realized, and the performance of (0112) oriented antimony is superior to that of (0001) oriented antimony.

As shown in FIG. 5, Raman spectroscopy is performed at room temperature on 15 nm (011̅2) antimony film deposited MoS₂ film using Raman spectrometer, wherein the antimony film has characteristic peaks of 111 cm⁻¹ and 149 cm⁻¹, demonstrating that the evaporated and deposited (011̅2) antimony film is semi-metallic.

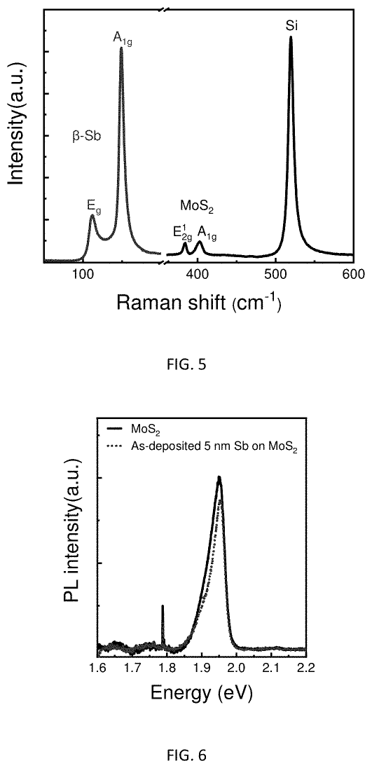

As shown in FIG. 6, the photoluminescence spectrum test at 6K is performed on 5 nm (011̅2) antimony film deposited on MoS₂ film using the low-temperature photoluminescence spectrometer, wherein the low-temperature photoluminescence spectrum of the MoS₂ does not have significant peak position movement before and after the deposition of the antimony film, and a defect peak is not seen in the range of 1.6-1.8 eV, which indicates that MoS₂ is not destroyed or damaged during the deposition process of (011̅2) antimony film.

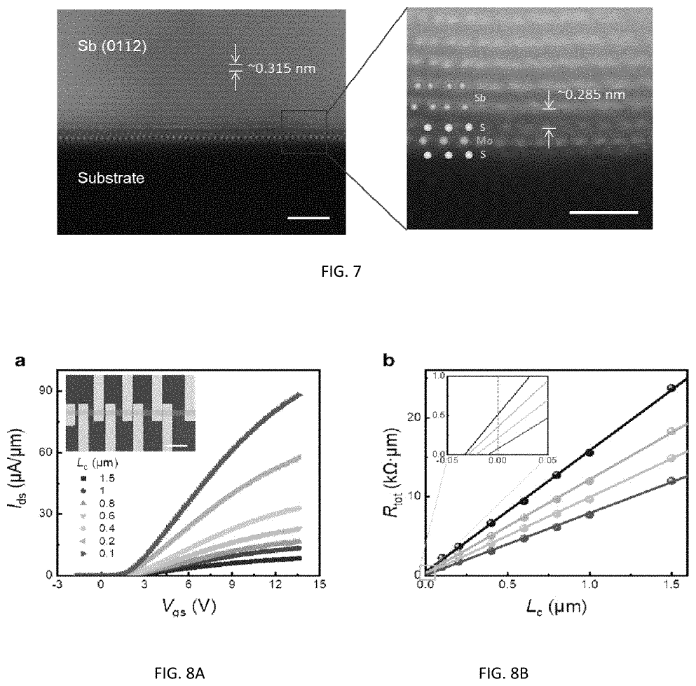

The structure of the antimony (0112) film-MoS₂ contact is characterized using the transmission electron microscope, and as shown in left of FIG. 7, antimony atoms and MoS₂ are arranged in parallel, and the interlayer spacing of antimony atoms is about 0.315 nm, which is consistent with the theoretical structure of (011̅2) antimony film. Right of FIG. 7 shows the local high-resolution image having perfect atomic stacking, which again indicates that there is no defect generated between the (011̅2) antimony film and MoS₂.

In another embodiment of the present invention, two-dimensional semiconductor transistors with the ohmic contact are prepared on the heavily doped silicon substrate, and the preparation process comprises the following steps:
(1) depositing 14-nm hafnium oxide on the heavily doped silicon substrate by the atomic layer deposition system; putting the substrate into the atomic layer deposition cavity, vacuum the cavity, heating to 150° C., keeping for 10 min, and growing for 110 cycles with the tetrakis (dimethylamino) hafnium as the metal source and the oxygen plasma as the oxidation source; and taking out the substrate when the deposition process is finished;
(2) transferring the MoS₂ film from the sapphire substrate to the hafnium oxide/heavily doped silicon substrate described previously; spin-coating the sapphire substrate growing the MoS₂ film with a PMMA supporting layer, wherein the spin-coating conditions are as follows: spin coating at 2000 rpm for 1 min, and baking at 150° C. on a hot plate for 2 min; then attaching the thermal release adhesive tape on the surface; placing the substrate in a 2 mol/L potassium hydroxide solution, wherein potassium hydroxide can etch the sapphire substrate, and after molybdenum sulfide is separated from the sapphire, washing the structure of the thermal release adhesive tape/PMMA/MoS2 with deionized water for several times, attaching the structure on the hafnium oxide/heavily doped silicon substrate, and heating by using a hot plate to release the thermal release adhesive tape;
(3) patterning the continuous MoS₂ film into strips by using the PMMA of the step (2) as the mask layer and using the electron beam lithography system and the plasma etching system (ICP), and removing redundant PMMA with acetone;
(4) spin-coating the sample with a layer of PMMA as the mask layer, patterning the electrode patterns of the two-dimensional semiconductor devices by using the electron beam lithography system, placing the sample in the electron beam evaporation system, vacuuming for 5 h with the vacuum degree of about 1×10⁻⁷ Torr, opening the heating mercury lamp, heating the temperature of the cavity to 150° C., and determining the temperature of the sample as 100° C. according to the measurement result of the attached temperature sticker; and
(5) opening the electron beam filament, heating the crucible filled with the high-purity antimony, and performing vacuum evaporation on antimony for 20 nm; opening the shielding plate, performing (011̅2) antimony film deposition on the sample at the evaporation rate of 0.05-0.3 A/s for 20 nm; then performing evaporation for 40 nm on the surface at the evaporation rate of 0.3-0.6 A/s; after the evaporation process is finished, taking out the sample; and lift-off to remove excess PMMA, and blowing the sample with nitrogen gun to dryness.

The device prepared in this embodiment is placed on the vacuum probe station, vacuuming to 10⁻⁵ Pa, and subjected to electrical measurement, and the specific results are as follows:

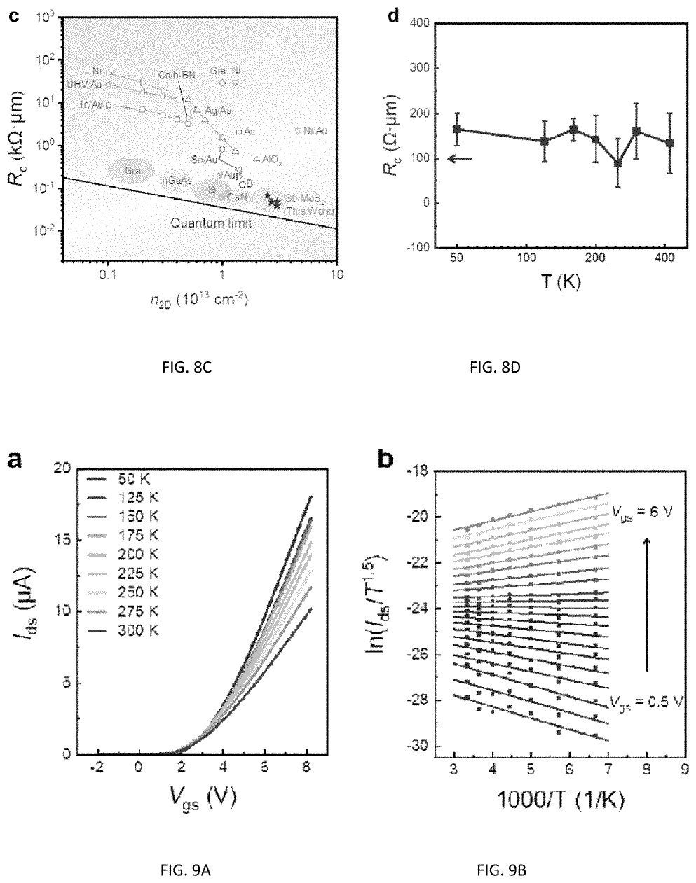

Contact resistance measurement: FIG. 8A shows transfer curves of the prepared MoS₂ devices with different channel lengths, wherein the channel lengths are 0.1 μm, 0.2 μm, 0.4 μm, 0.6 μm, 0.8 μm, 1.0 μm and 1.5 μm, respectively, and the source-drain voltage is 0.1 V; the inset is the false-color scanning electron microscope image of corresponding devices; as shown in FIG. 8B, the contact resistance of the MoS₂ device is extracted by the transmission line model, and when the carrier concentration is 3×10¹³ cm², the contact resistance is 42 Ω·μm (close to the quantum limit), and the corresponding transfer length is 5.1 nm, which is the lowest result reported in two-dimensional semiconductor devices filed at present.

Furthermore, as shown in FIG. 8C, comparing the results of the present invention with those of other techniques, higher concentration of carriers (3×10¹³ cm⁻²) and smaller contact resistance (˜42 Ω·μm) are achieved, which are lower than those of semiconductor devices such as silicon and gallium nitride and close to the quantum limit.

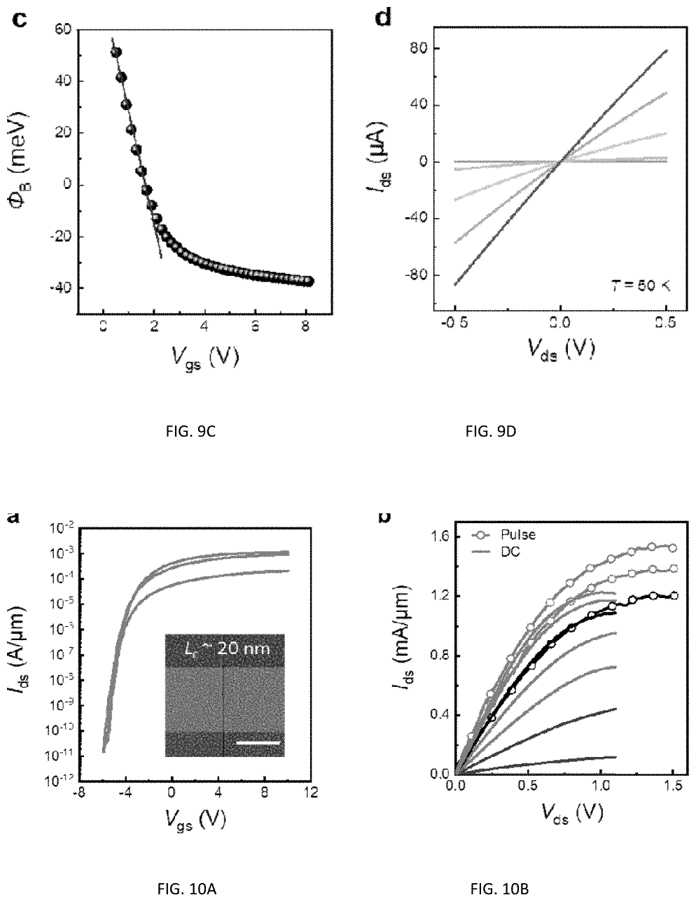

Schottky barrier measurement: the temperature-dependent measurement of another set of MoS₂ devices is performed at the temperature range of 50-400 K, and the contact resistances under different temperatures are extracted in the same manner, and as can be seen from FIG. 8D, the contact resistance is temperature independent in the entire range, suggesting that the cross-junction transport was through tunneling instead of thermionic emission. This was strong evidence for Ohmic contact. Besides, the Schottky barrier between semimetal antimony (0112) and MoS₂ is extracted from the variable-temperature measurements, and FIG. 9A-C are transfer curves at different temperatures, Arrhenius curves and the barrier curve of the two-dimensional MoS₂ device, respectively, with the Schottky barrier of −20 meV, and as can be seen from output curves (FIG. 9D) of 50 K, the output curves still maintain high linearity at 50 K, which fully proves that the ohmic contact exists between semimetal antimony (011̅2) and MoS₂.

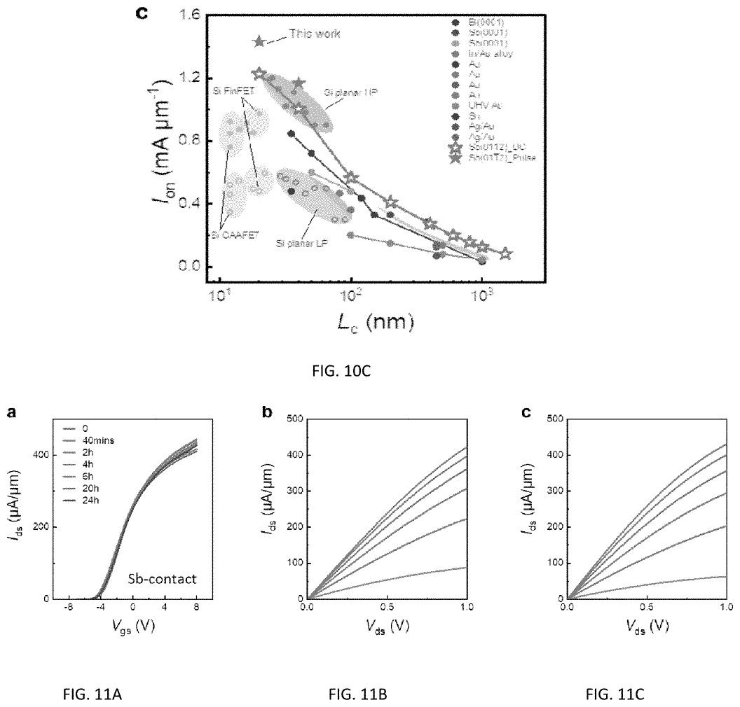

High performance short channel device measurements: the inset in FIG. 10A shows the scanning electron microscope image of a typical monolayer MoS₂ transistor with the channel length of 20 nm. FIG. 10A-B show the transfer and output curves of this device, and as can be seen from the data, the device has high on/off ratio of 10⁹ and negligible drain induced barrier lowering (DIBL) effect and small saturation voltage of 1 V, and especially at the source-drain voltage of 1.5 V, the on-state current is as high as 1.54 mA/μm in the pulse test mode, which is the highest reported result for the two-dimensional semiconductor devices at present. In addition, comparing the reported results of other technologies, the five-pointed stars in the figure are the measurement result of this embodiment, and as can be seen from FIG. 10C, the prepared monolayer MoS₂ device shows excellent performance characteristics from long channel to short channel, reaching the level of planar silicon device, higher than the result of silicon-based Fin FET and GAAFET, and higher than the performance requirements of the international device and system roadmap on logic devices in 2028.

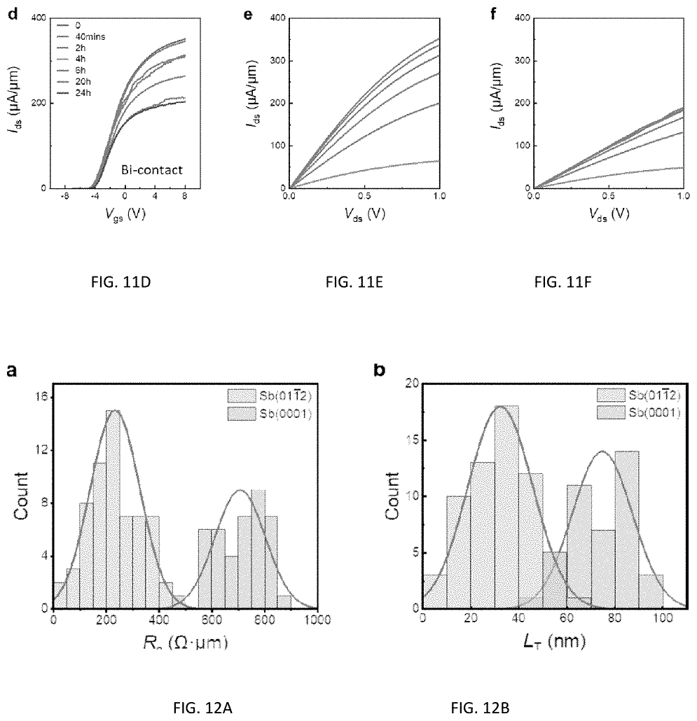

High-temperature reliability measurement: the thermal reliability measurement is performed on MoS₂ devices with antimony (011̅2)-contact and bismuth-contact in the nitrogen environment at 125° C. (the upper limit of working temperature for electronic devices). As shown in FIG. 11A-C, repeated measurements of an antimony (011̅2) contact device at 125° C. for different time periods exhibit striking repeatability, with no decay of the on-state current of the device after 24 h at 125° C.; as shown in FIG. 11D-F, the on-state current of a comparative bismuth contact device gradually decreases over time, with the degeneration of 41% after 24 h. The comparison shows that the contact between semimetal antimony (0112) and two-dimensional semiconductor has more excellent thermal stability.

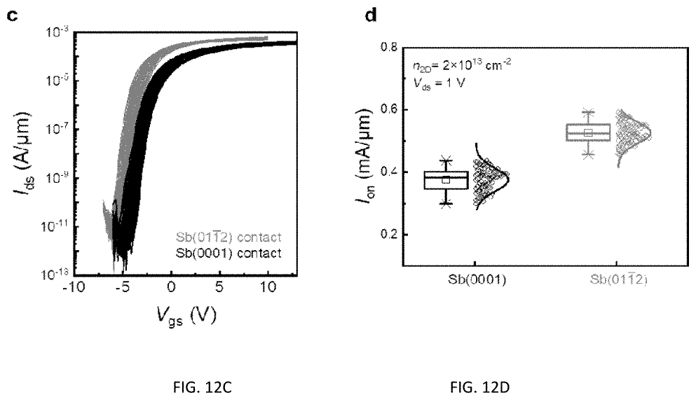

Statistical measurement of transistor arrays: the electrical measurements are performed on transistor arrays with antimony (011̅2) contact and antimony (0001) contact, respectively. The statistical distribution of the contact resistance and the transfer length of the devices with these two contacts is performed by using the above-mentioned transmission line model; FIG. 12A-B are the histogram statistical results of the contact resistance and the transfer length of the antimony (011̅2)-MoS₂ contact and the antimony (0001)-MoS₂ contact, respectively, and it can be seen from the figure that the average contact resistance of the antimony (011̅2) contact is 232±94 Ω μm, which is 3.1 times lower than that of the antimony (0001) contact. The transfer lengths have the same trend result. This indicates that antimony (011̅2) can achieve high stability and highly reproducible contact with two dimensional materials. In addition, statistical measurement analysis is also performed on the MoS₂ devices of a 100-nm channel length with these two contacts, and as shown in FIG. 12C-D, the antimony (011̅2) contact device has higher on-state current density, on average 38% higher than the antimony (0001) contact device due to the lower contact resistance of the antimony (011̅2) contact, which further demonstrates the high efficiency of carrier injection at the antimony (0112)-MoS₂ contact interface.

The present invention deposits the semimetal antimony (011̅2) as the contact electrode through the high-temperature evaporation process, inhibits the metal-induced energy gap state in metal-semiconductor contact, and strengthens the van der Waals interaction and the energy band hybridization between the metal and the semiconductor. A two-dimensional MoS₂ transistor with the contact resistance as low as 42 Ω·μm, the transfer length as low as 5.1 nm and the current density of 1.54 mA/μm under the source-drain voltage of 1.5 V is prepared for the first time. Meanwhile, this ohmic contact technology has high temperature reliability and high repeatability, and is suitable for various types of two-dimensional semiconductor devices, including any one of back-gate field-effect transistors, top-gate field-effect transistors, the triodes, diodes, phototransistors, junction transistors, metal-semiconductor transistors, SOI transistors, modulation doped field-effect transistors, thyristors, LEDs, photodetectors, laser diodes, power semiconductor devices, ferroelectric transistors, Fin FETs, GAA FETs, MBC FETs, CFETs and 3D EFTs.

The vacuum deposition of the present invention is not limited to the method disclosed in the embodiment, and thermal evaporation, magnetron sputtering, molecular-beam epitaxy, plasma enhanced chemical deposition, laser pulse deposition, atomic layer deposition, chemical vapor deposition and physical vapor deposition may be applied as well.

The above description is used for illustrating the present invention with the preferred embodiments. However, the above description is only for the purpose of understanding the present invention by those skilled in the art and is not intended to limit the scope of claims of the present invention. For those skilled in the art, the description, when within the spirit of the present invention, are readily related to various equivalent changes. Therefore, all the equivalent changes or modifications based on the concept and spirit of the present invention shall fall within the protection scope of the present invention. It is not necessary for any embodiment or claim of the present invention to address all of the objectives or advantages or features disclosed herein.

What is claimed is:

1. An ohmic-contact structure, comprising two-dimensional semiconductor materials having semimetal antimony or an alloy containing semimetal antimony deposited thereon to form an ohmic contact.

2. The ohmic-contact structure according to claim 1, wherein the semimetal antimony and the alloy thereof are (011̅2) oriented.

3. The ohmic-contact structure according to claim 1, wherein the two-dimensional semiconductor includes any one of molybdenum disulfide (MoS₂), tungsten disulfide (WSe₂), molybdenum diselenide (MoSe₂), tungsten diselenide (WS₂), rhenium disulfide, black phosphorus, silicene, phosphorus selenide, germanene, indium selenide and tin sulfide.

4. The ohmic-contact structure according to claim 1, wherein the ohmic-contact structure is prepared by the following steps:
placing a sample having the two-dimensional semiconductor in high-vacuum evaporation system; and
heating the cavity to a preset temperature after vacuum pumping and performing vacuum evaporation process to finish the deposition of the semimetal antimony or the alloy containing semimetal antimony on the two-dimensional semiconductor material layer.

5. The ohmic-contact structure according to claim 4, wherein the vacuum pumping is performed to the vacuum degree higher than 10⁻⁶ Torr with the preset temperature range of 50-600° C., and the evaporation of metal is performed at a rate of 0.05-0.3 A/s for 1-30 nm.

6. The ohmic-contact structure according to claim 4, wherein the high-vacuum evaporation systems include electron beam vacuum evaporation, magnetron sputtering deposition or thermal evaporation.

7. A semiconductor device comprising the ohmic-contact structure according to claim 1, wherein the semiconductor device includes any one of back-gate field-effect transistors, top-gate field-effect transistors, triodes, diodes, phototransistors, junction transistors, metal-semiconductor transistors, SOI transistors, modulation doped field-effect transistors (FETs), thyristors, LEDs, photodetectors, laser diodes, power semiconductor devices, ferroelectric transistors, Fin FETs, GAA FETs, MBC FETs, CFETs and 3D EFTs.

8. A semiconductor device comprising a metal-semiconductor contact structure, comprising a substrate with gate stacks and the ohmic-contact structure according to claim 1 deposited on the substrate, wherein the ohmic-contact structure has a capping layer deposited thereon, and the substrate has a gate and a gate dielectric layer.

9. The semiconductor device comprising a metal-semiconductor contact structure according to claim 8, wherein the gate dielectric layer is at least one of silicon oxide, hafnium oxide, aluminum oxide, zirconium oxide, lanthanum oxide, titanium oxide, boron nitride, mica, silicon nitride, PZT and HZO; the gate is any one of a conductive metal, ITO, heavily doped silicon, graphene and a metallic carbon nanotube, and the capping layer is at least one of gold, silver, copper, aluminum, platinum, nickel, titanium, ITO, tungsten, palladium, cobalt and molybdenum.

10. The semiconductor device comprising a metal-semiconductor contact structure according to claim 8, wherein the substrate is any one of silicon oxide, sapphire, quartz, glass, silicon nitride, polyimide, PDMS, PMMA, BCB, PET and PEN.
